(19) United States
(12) Patent Application Publication
(10) Pub. No.: US 2025/0176129 A1
(43) Pub. Date: May 29, 2025

(54) Server System Multi Access Option Storage System

(71) Applicant: Dell Products L.P., Round Rock, TX (US)

(72) Inventors: James Utz, Georgetown, TX (US); Man Tak Ho, Austin, TX (US); Yen-Hsing Lin, Datong Dist. (TW)

(21) Appl. No.: 18/520,615

(22) Filed: Nov. 28, 2023

(51) Int. Cl. H05K 7/14; G06F 1/16

(52) U.S. Cl. CPC H05K 7/1487; G06F 1/1679

(57) ABSTRACT

A storage system. The storage system includes a storage system cartridge module; and, a storage system housing, the storage system housing comprising a bottom wall and a front housing portion, the front housing portion extending substantially perpendicularly from the bottom wall, the front housing portion comprising a multi access option feature, the multi access option feature enabling a common storage system housing to be used with storage cartridge modules having a plurality of storage system access options.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing a storage system with a plurality of storage module access options.

In one embodiment, the invention relates to a storage system housing for use with storage module system for an information handling system, comprising: a bottom wall; and, a front housing portion, the front housing portion extending substantially perpendicularly from the bottom wall, the front housing portion comprising a multi access option feature, the multi access option feature enabling a common storage system housing to be used with storage cartridge modules having a plurality of storage system access options.

In another embodiment, the invention relates to a storage system comprising: a storage system cartridge module; and, a storage system housing, the storage system housing comprising a bottom wall; and, a front housing portion, the front housing portion extending substantially perpendicularly from the bottom wall, the front housing portion comprising a multi access option feature, the multi access option feature enabling a common storage system housing to be used with storage cartridge modules having a plurality of storage system access options.

In another embodiment, the invention relates to a system comprising: a processor; a data bus coupled to the processor; and a storage system comprising a storage system cartridge module; and, a storage system housing, the storage system housing comprising a bottom wall; and, a front housing portion, the front housing portion extending substantially perpendicularly from the bottom wall, the front housing portion comprising a multi access option feature, the multi access option feature enabling a common storage system housing to be used with storage cartridge modules having a plurality of storage system access options.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIGS. 4A and 4B, generally referred to as FIG. 4, show a multi access option storage system with a plurality of storage system access option configurations.

FIG. 5 shows a perspective view of a storage system housing of a multi access option storage system.

FIGS. 6A and 6B, generally referred to as FIG. 6, show a perspective views of a plurality of storage cartridges of a multi access option storage system.

FIG. 7 shows an exploded perspective view of a storage cartridge of a multi access option storage system.

FIGS. 8A and 8B, generally referred to as FIG. 8, show examples of multi access option storage systems installed in an information handling system.

### DETAILED DESCRIPTION

Various aspects of the disclosure include an appreciation that it is known to provide information handling systems with storage systems such as boot optimized storage systems. Various aspects of the disclosure include an appreciation that it is known to storage systems, such as boot optimized storage systems, which are hot swappable. Various aspects of the present disclosure include an appreciation that certain customers can require systems having storage systems which are not easily removed and are lockable. Various aspects of the present disclosure include an appreciation that with these customers, hot swappable storage systems are not acceptable. Various aspects of the present disclosure include an appreciation that it would be desirable to provide storage systems which are lockable.

A system and method are disclosed for providing a multi access option storage system which may be configured in a plurality of storage system access options. In certain embodiments, the plurality of storage system access options can include a hot swap storage media access option and a locking storage media access option. In certain embodiments, a single storage module of the storage system can be configured with the plurality of storage system access options. In certain embodiments, the hot swap storage media access option uses a storage cartridge module that is configured to allow hot swapping of the storage cartridge. In certain embodiments, the storage cartridge module includes a latch which allows a user to unlatch the storage cartridge module and remove the storage cartridge module from the storage system.

In certain embodiments, the locking storage media access option uses a storage cartridge module that is configured to allow locking of the storage cartridge. In certain embodiments, the storage cartridge module includes a locking cartridge. In certain embodiments, the locking cartridge has no latch, no pull handling, or no combination thereof. In certain embodiments, the locking cartridge includes a fastener which prevents a user from easily removing the storage cartridge module from the storage system. In certain embodiments, the locking storage module access option includes a flush mounted faceplate which is secured by a fastener that can only be accessed when the storage module is not installed in a system. In certain embodiments, the fastener is not accessible once the storage system is installed in an information handling system. In certain embodiments, the locking cartridge can only be accessed by removing the information handling system from a rack in which the information handling system is installed.

Accordingly, the multi access option storage system provides a plurality of different carrier designs that are compatible with the same storage system module. In certain embodiments, the multi access option storage system allows either a hot swap storage media access option or a locking storage media access option to be selected and installed, resulting in either hot swap functionality or locking functionality being enabled using the same storage system module.

In certain embodiments, the storage system comprises a boot optimized storage system. In certain embodiments, the boot optimized storage system comprises a redundant array of independent disks (RAID) solution optimized for booting an operating system of a server. In certain embodiments, the boot optimized storage system comprises a plurality of serial advanced technology advancement (SATA) solid state devices (SSDs), a host interface (such as a PCIe host interface), a device interface (such as a SATA device interface), or a combination thereof.

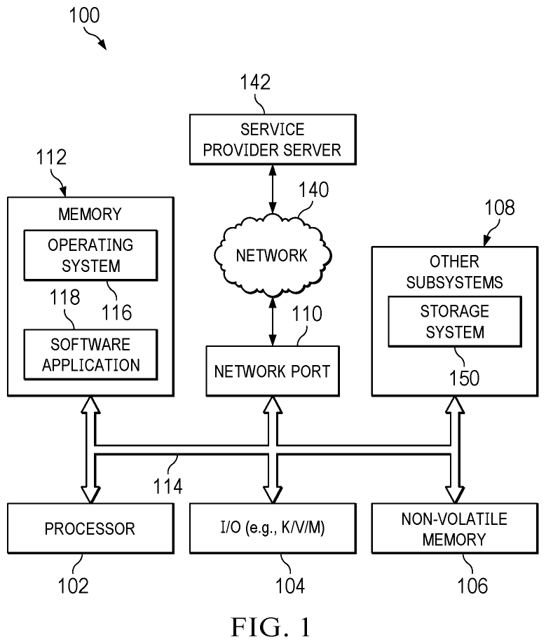

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, one or both the other subsystems 108 or the network port 110 include storage system 150. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the storage system 150 comprises a multi access option storage system which may be configured in a plurality of storage system access options. In certain embodiments, the plurality of storage system access options can include a hot swap storage media access option and a locking storage media access option. In certain embodiments, a single storage module of the storage system can be configured with the plurality of storage system access options. In certain embodiments, the hot swap storage media access option uses a storage cartridge module that is configured to allow hot swapping of the storage cartridge. In certain embodiments, the storage cartridge module includes a latch which allows a user to unlatch the storage cartridge module and remove the storage cartridge module from the storage system. In certain embodiments, the storage system 150 includes a plurality of multi access option features which enable a common storage system housing to be used with storage cartridge modules having a plurality of storage system access options.

In certain embodiments, the locking storage media access option uses a storage cartridge module that is configured to allow locking of the storage cartridge. In certain embodiments, the storage cartridge module includes a locking cartridge. In certain embodiments, the locking cartridge has no latch, no pull handling, or no combination thereof. In certain embodiments, the locking cartridge includes a fastener which prevents a user from easily removing the storage cartridge module from the storage system. In certain embodiments, the locking storage module access option includes a flush mounted faceplate which is secured by a fastener that can only be accessed when the storage module is not installed in a system. In certain embodiments, the fastener is not accessible once the storage system is installed in an information handling system. In certain embodiments, the locking cartridge can only be accessed by removing the information handling system from a rack in which the information handling system is installed.

In various embodiments, the storage module system includes one or more multi access option features which enable a common storage system to be used with storage cartridge modules having a plurality of storage system access options. In various embodiments, the multi access option features include a latching component, a locking component, a multi access option storage system housing, or a combination thereof. In various embodiments, the multi access option storage system housing includes one or more multi access option features. In various embodiments, the multi access option features of the multi access option storage system housing include one or more latching portions, one or more locking apertures, or a combination thereof. In various embodiments, certain multi access option features interact with other multi access option features depending on the storage system media access configuration.

Accordingly, the multi access option storage system provides a plurality of different carrier designs that are compatible with the same storage system module. In certain embodiments, the multi access option storage system allows either a hot swap storage media access option or a locking storage media access option to be selected and installed, resulting in either hot swap functionality or locking functionality being enabled using the same storage system module.

In certain embodiments, the storage system comprises a boot optimized storage system. In certain embodiments, the boot optimized storage system comprises a redundant array of independent disks (RAID) solution optimized for booting an operating system of a server. In certain embodiments, the boot optimized storage system comprises a plurality of serial advanced technology advancement (SATA) solid state devices (SSDs), a host interface (such as a PCIe host interface), a device interface (such as a SATA device interface), or a combination thereof.

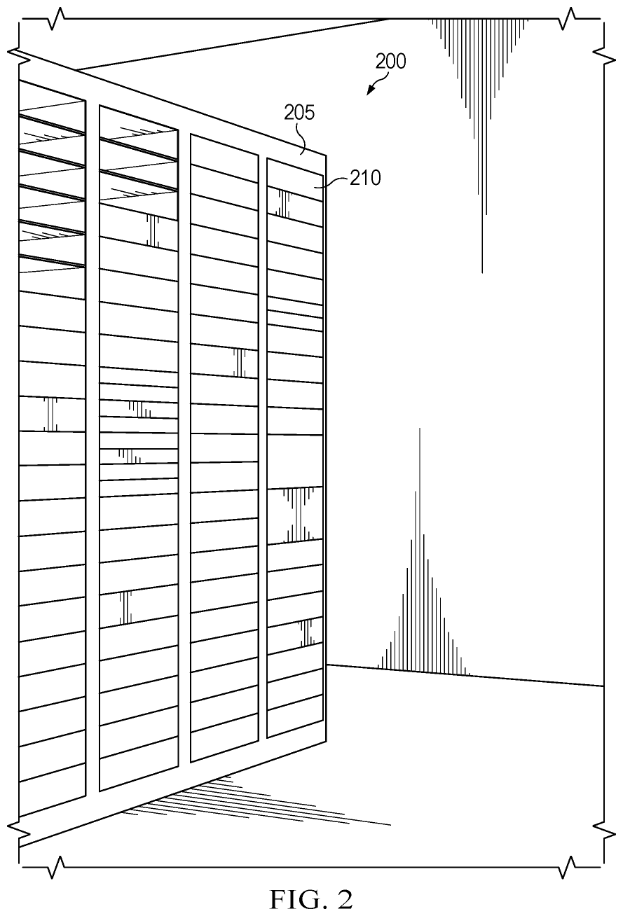

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100 as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1 U rack unit, a 2 U rack unit and a 4 U rack unit. In general, a 1 U rack unit is substantially (i.e., +/−20%) 1.75″ high, a 2 U rack unit is substantially (i.e., +/−20%) 3.5″ high and a 4 U rack height is substantially (i.e., +/−20%) 7.0″ high.

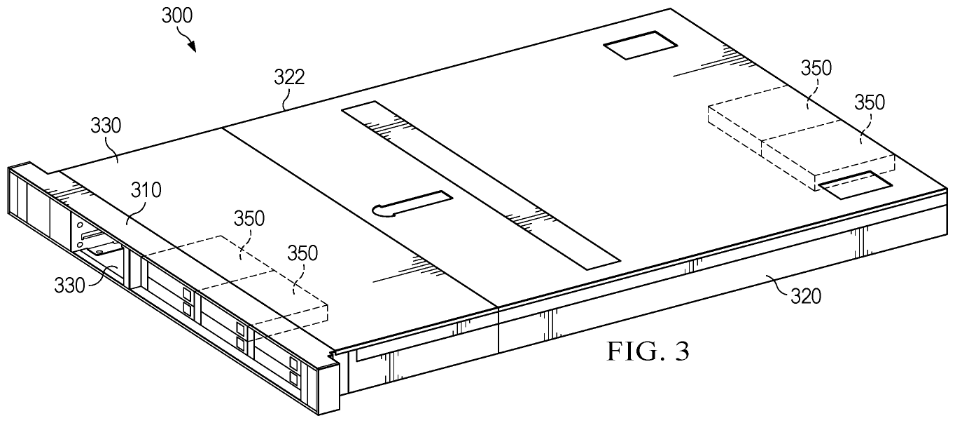

FIG. 3 shows a generalized perspective view of an example blade server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300. In certain embodiments, the blade type information handing system 300 includes a bay 350 via which components may be mounted to the blade type information handling system.

In certain embodiments, components mounted in one or more of the bays 310 include a multi access option storage system 350 which may be configured in a plurality of storage system access options. In certain embodiments, the plurality of storage system access options can include a hot swap storage media access option and a locking storage media access option. In certain embodiments, a single storage module of the storage system can be configured with the plurality of storage system access options. In certain embodiments, the hot swap storage media access option uses a storage cartridge module that is configured to allow hot swapping of the storage cartridge. In certain embodiments, the storage cartridge module includes a latch which allows a user to unlatch the storage cartridge module and remove the storage cartridge module from the storage system.

In certain embodiments, the locking storage media access option uses a storage cartridge module that is configured to allow locking of the storage cartridge. In certain embodiments, the storage cartridge module includes a locking cartridge. In certain embodiments, the locking cartridge has no latch, no pull handling, or no combination thereof. In certain embodiments, the locking cartridge includes a fastener which prevents a user from easily removing the storage cartridge module from the storage system. In certain embodiments, the locking storage module access option includes a flush mounted faceplate which is secured by a fastener that can only be accessed when the storage module is not installed in a system. In certain embodiments, the fastener is not accessible once the storage system is installed in an information handling system. In certain embodiments, the locking cartridge can only be accessed by removing the information handling system from a rack in which the information handling system is installed.

Accordingly, the multi access option storage system provides a plurality of different carrier designs that are compatible with the same storage system module. In certain embodiments, the multi access option storage system allows either a hot swap storage media access option or a locking storage media access option to be selected and installed, resulting in either hot swap functionality or locking functionality being enabled using the same storage system module.

In certain embodiments, the storage system comprises a boot optimized storage system. In certain embodiments, the boot optimized storage system comprises a redundant array of independent disks (RAID) solution optimized for booting an operating system of a server. In certain embodiments, the boot optimized storage system comprises a plurality of serial advanced technology advancement (SATA) solid state devices (SSDs), a host interface (such as a PCIe host interface), a device interface (such as a SATA device interface), or a combination thereof.

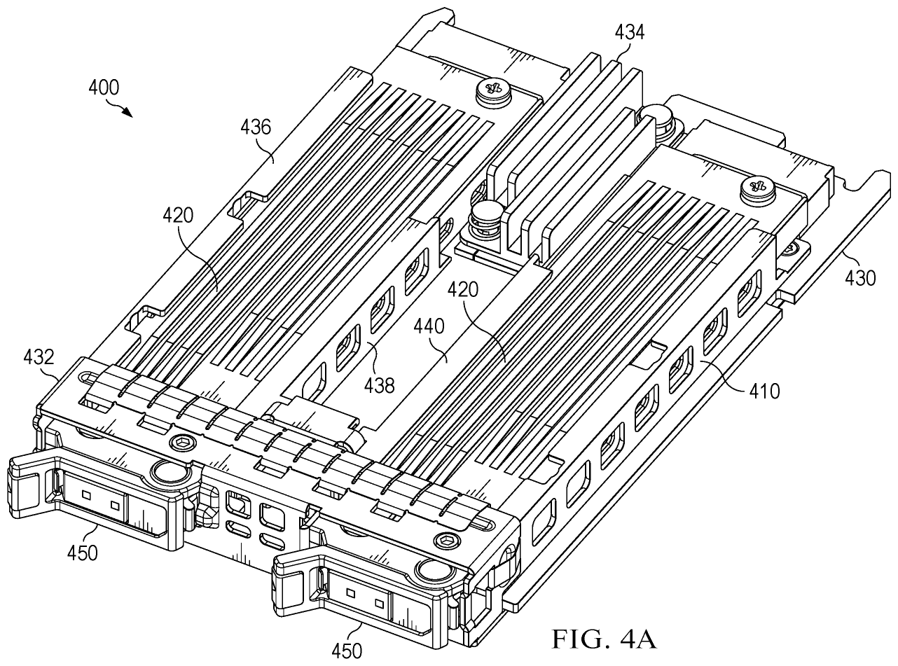

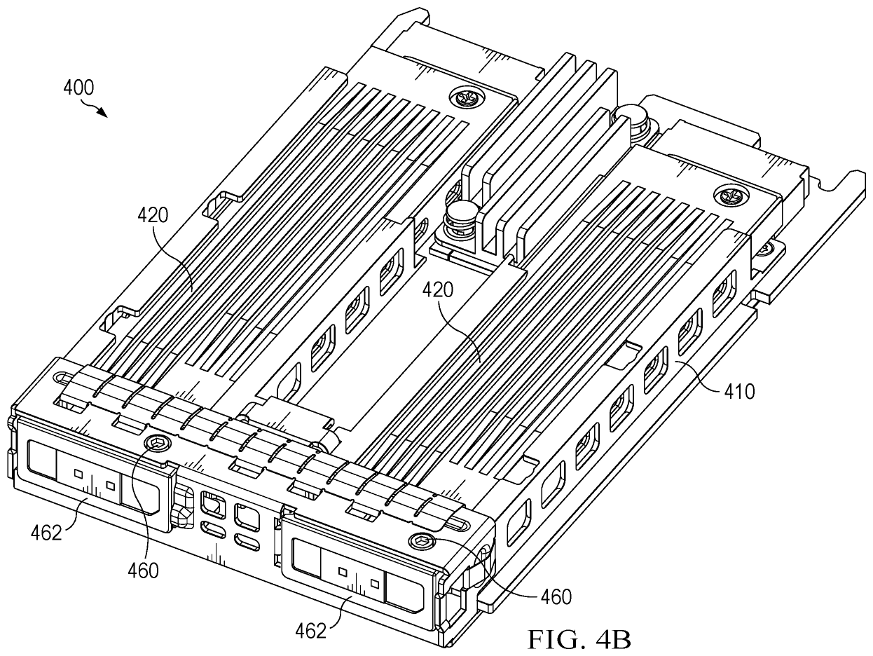

FIGS. 4A and 4B, generally referred to as FIG. 4, show a multi access option storage system 400 with a plurality of storage system access option configurations. More specifically, FIG. 4A shows a multi access option storage system with a hot swap storage system access option configuration. FIG. 4B shows a multi access option storage system 400 with a locking storage system access option configuration. In certain embodiments, the multi access option storage system 400 includes a storage system housing 410, one or more storage cartridge modules 420, or a combination thereof. In certain embodiments, the one or more storage cartridge modules 420 are configured according to one of a plurality of storage system access option configurations.

In certain embodiments, a single storage module housing 410 can be configured with the plurality of storage system access options. In certain embodiments, the plurality of storage system access options can include a hot swap storage media access option and a locking storage media access option. In certain embodiments, the hot swap storage media access option uses a storage cartridge module 420 that is configured to allow hot swapping of the storage cartridge. In certain embodiments, the locking storage media access option uses a storage cartridge module 420 that is configured to allow locking of the storage cartridge.

In certain embodiments the storage module housing 410 includes a bottom wall 430, a front housing portion 432, an outside right wall 434, an outside left wall 436, an inside right wall 438, an inside left wall 440, or a combination thereof.

In certain embodiments, the housing portion 432 extends substantially perpendicularly (i.e., +/−20%) from the bottom wall 430. In certain embodiments, the front wall extends substantially perpendicularly (i.e., +/−20%) from the bottom wall 430. In certain embodiments, the outside right wall 434 extends substantially perpendicularly (i.e., +/−20%) from the bottom wall 430. In certain embodiments, the outside left wall 436 extends substantially perpendicularly (i.e., +/−20%) from the bottom wall 430. In certain embodiments, the right inside wall 438 extends substantially perpendicularly (i.e., +/−20%) from the bottom wall 430. In certain embodiments, the left inside wall 440 extends substantially perpendicularly (i.e., +/−20%) from the bottom wall 430. It will be appreciated that the orientations of the walls will be reversed when the storage system is installed at the rear of the information handling systems (e.g., the front housing portion 432 is effectively a rear housing portion).

In certain embodiments, the front housing portion 432 defines one or more apertures via which storage cartridge modules 420 may be installed in the storage module housing 410. In certain embodiments pairs of left and right walls (e.g., a left outside wall and a right inside wall) include channels via which respective storage cartridges may be inserted and mounted to the storage module housing 410. In certain embodiments, the left and right walls include channels via which respective storage cartridges may be inserted and mounted to the storage module housing 410. In certain embodiments, the outside right wall 434 and the inside left wall 440 define channels via which a storage cartridge module 420 may be installed in the storage module housing 410. In certain embodiments, the outside left wall 436 and the inside right wall 438 define channels via which a storage cartridge module 420 may be installed in the storage module housing 410.

In certain embodiments, when the storage cartridge module 420 is configured in a hot swap storage media access configuration, each storage cartridge module 420 includes a respective latch 450 which allows a user to unlatch the storage cartridge module and remove the storage cartridge module from the storage system.

In certain embodiments, when the storage system is configured in a locking configuration, each storage module includes a locking cartridge. In certain embodiments, the locking cartridge has no latch, no pull handle, or no combination thereof. In certain embodiments, the locking cartridge includes a fastener 460 which prevents a user from easily removing the storage cartridge module from the storage system. In certain embodiments, the locking storage module access option includes a flush mounted faceplate 642 which is secured by the fastener 460. In certain embodiments, the fastener 460 can only be accessed when the storage module is not installed in an information handling system. In certain embodiments, the fastener is not accessible once the storage system is installed in an information handling system. In certain embodiments, the locking cartridge can only be accessed by removing the information handling system from a rack in which the information handling system is installed.

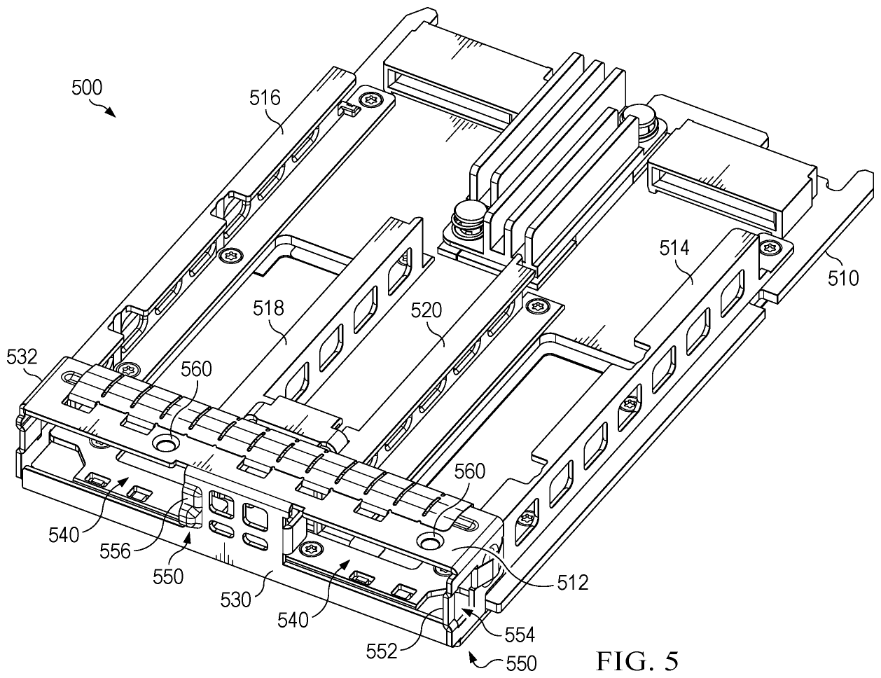

FIG. 5 shows a perspective view of a storage system housing 500 of a multi access option storage system. In certain embodiments, the storage system housing 500 corresponds to storage system housing 410. In certain embodiments, the storage system housing 500 is designed to function with a boot optimized storage system.

In certain embodiments the storage module housing 410 includes a bottom wall 510, a front housing portion 512, an outside right wall 514, an outside left wall 516, an inside right wall 518, an inside left wall 520, or a combination thereof. In certain embodiments, the front housing portion 512 extends substantially perpendicularly (i.e., +/−20%) from the bottom wall 510. In certain embodiments, the front wall extends substantially perpendicularly (i.e., +/−20%) from the bottom wall 510. In certain embodiments, the outside right wall 514 extends substantially perpendicularly (i.e., +/−20%) from the bottom wall 510. In certain embodiments, the outside left wall 516 extends substantially perpendicularly (i.e., +/−20%) from the bottom wall 510. In certain embodiments, the right inside wall 518 extends substantially perpendicularly (i.e., +/−20%) from the bottom wall 510. In certain embodiments, the left inside wall 520 extends substantially perpendicularly (i.e., +/−20%) from the bottom wall 510. It will be appreciated that the orientations of the walls will be reversed when the storage system is installed at the rear of the information handling systems (e.g., the front housing portion 512 is effectively a rear housing portion).

In certain embodiments pairs of left and right walls (e.g., a left outside wall and a right inside wall) include channels via which respective storage cartridges may be inserted and mounted to the storage module housing 410. In certain embodiments, the left and right walls include channels via which respective storage cartridges may be inserted and mounted to the storage module housing 410. In certain embodiments, the outside right wall 514 and the inside left wall 520 define channels via which a storage cartridge module 420 may be installed in the storage module housing 410. In certain embodiments, the outside left wall 516 and the inside right wall 518 define channels via which a storage cartridge module 420 may be installed in the storage module housing 410.

In certain embodiments, the front housing portion 512 includes a housing portion front wall 530 and a housing portion top wall 532. In certain embodiments, the housing portion front wall 530 extends substantially perpendicularly (i.e., +/−20%) from the bottom wall 510. In certain embodiments, the housing portion top wall 532 extends substantially perpendicularly (i.e., +/−20%) from the housing portion top wall 530. In certain embodiments, the housing portion front wall 530 provides a customer facing surface.

In certain embodiments, the housing portion front wall 530 defines one or more apertures 540 via which storage cartridge modules may be installed in the storage module housing 410. In certain embodiments, each aperture 540 includes a respective latching portion 550. In certain embodiments, a latching portion 550 includes a latch tab 552 and a latch aperture 554 via which a latch mates. In certain embodiments, the latch tab 552 and the latch aperture 554 are located on an outside wall of the housing portion 512. In certain embodiments, a latching portion 550 includes a latch bump out 556 via which a latch mates. In certain embodiments, the latch bump out 556 is located on the front wall 530 of the housing portion 512. In certain embodiments, the housing portion top wall 532 defines one or more housing locking apertures 560. In certain embodiments, a fastener secures a storage cartridge module to the storage module housing 500 when the storage system is configured in a locking configuration.

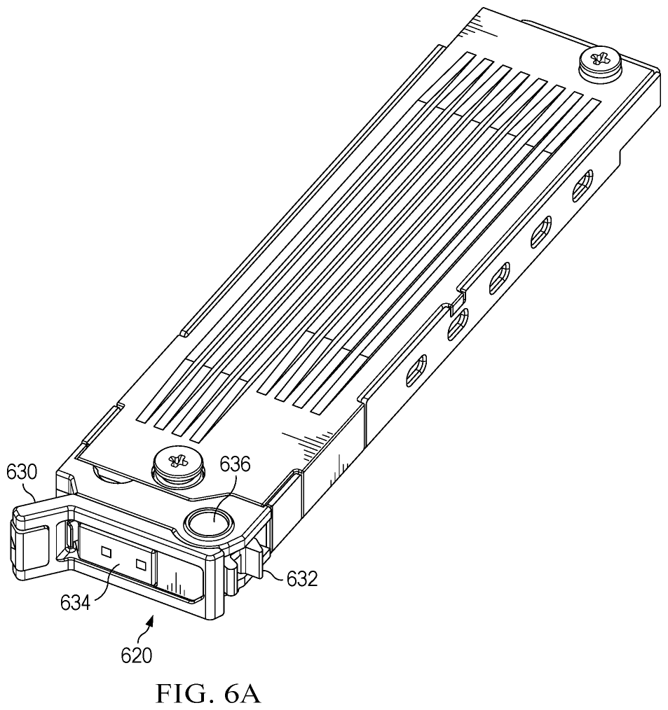

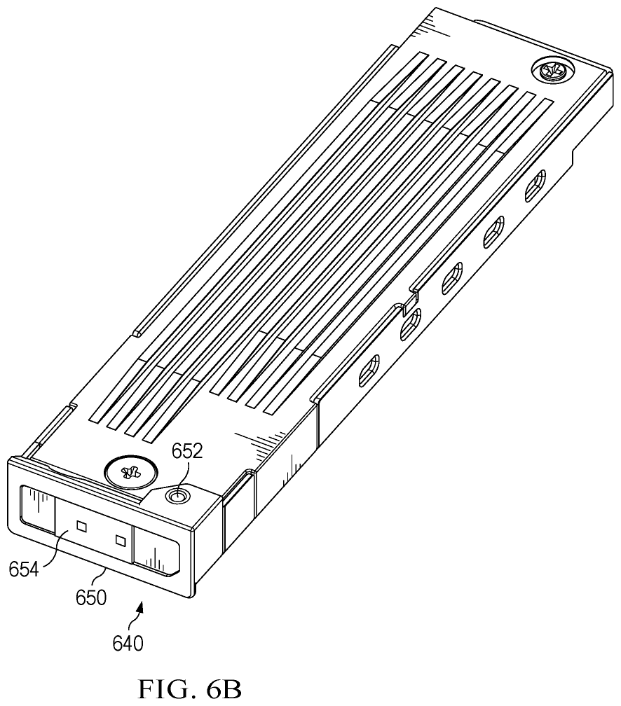

FIGS. 6A and 6B, generally referred to as FIG. 6, show a perspective views of a plurality of storage cartridge modules of a multi access option storage system. More specifically, FIG. 6A shows a storage cartridge module 600 when configured in a hot swap storage media access configuration. FIG. 6B shows a storage cartridge module 600 when configured in a locking configuration. In certain embodiments, the storage cartridge module 600 corresponds to storage cartridge module 420.

In certain embodiments, when the storage cartridge module 600 is configured in a hot swap storage media access configuration, the storage cartridge module 600 includes a latch component 620 which allows a user to unlatch the storage cartridge module and remove the storage cartridge module from the storage system. In certain embodiments, the latch component 620 includes a latch handle 630, a side latch portion 632, a status indicia portion 634, a pivot portion 636, or a combination thereof. In certain embodiments, the latch handle 530 is rotated outward to unlatch the storage cartridge module 600 from a storage module housing. In certain embodiments, the side latch portion 620 engages with the storage module housing when the storage cartridge module 600 is installed in a storage module housing. In certain embodiments, the status indicia portion 634 provides status information which is visually observable when the storage cartridge module 600 is installed in a storage module housing. In certain embodiments, the latch handle 630 pivots about the pivot portion 634 when the latch handle is rotated between an open position and a closed position.

In certain embodiments, when the storage system is configured in a locking configuration, the storage cartridge module 600 includes a locking component 640. In certain embodiments, the locking component 640 has no latch, no pull handle, or no combination thereof. In certain embodiments, the locking component 640 provides the storage cartridge module 600 with a flush mounted faceplate.

In certain embodiments, the locking component 640 includes a front face portion 650, a fastener aperture 652, a status indicia portion 654, or a combination thereof. In certain embodiments, the front face portion 650 is substantially flat and thus is not easily graspable by a user. In certain embodiments, the fastener aperture 652 is threaded to receive a locking fastener. In certain embodiments, the fastener aperture 652 aligns with a housing locking aperture when the storage cartridge module 600 is installed in a storage module housing. In certain embodiments, the locking fastener is inserted into the housing locking aperture and affixed to the fastener aperture 652 when the storage system is configured in a locking configuration. In certain embodiments, the status indicia portion 635 provides status information which is visually observable when the storage cartridge module 600 is installed in a storage module housing.

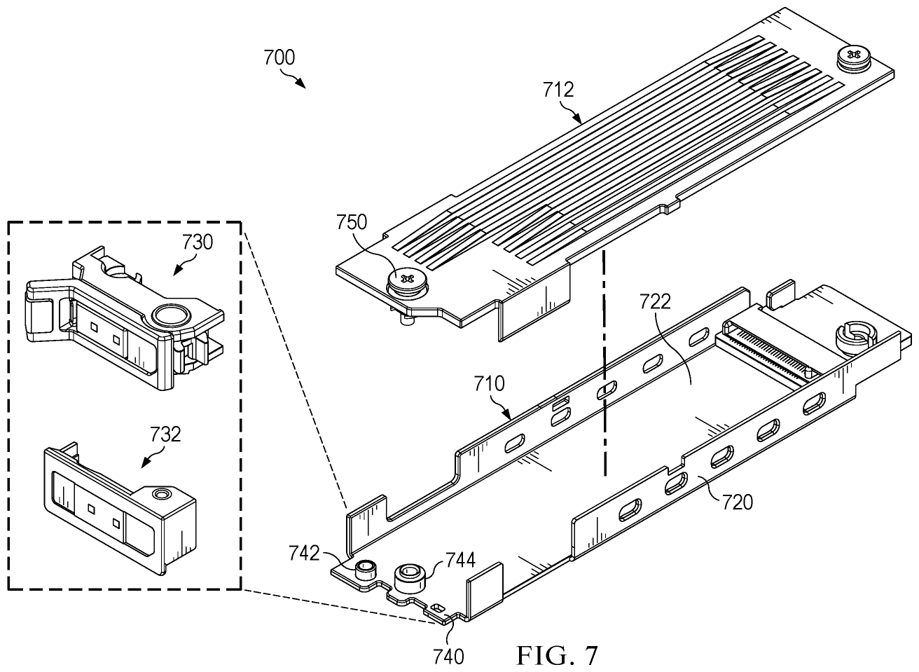

FIG. 7 shows an exploded perspective view of a storage cartridge module 700 of a multi access option storage system. In certain embodiments, the storage cartridge module 700 corresponds to storage cartridge module 420.

In certain embodiments the storage cartridge module 700 includes a bottom component 710 and a top cover 712. In certain embodiments, the bottom component 710 and the top cover 712 are common to the storage cartridge module 700 regardless of whether the storage cartridge module is configured in a hot swap storage media access configuration or a locking configuration. In certain embodiments, the bottom component 710 includes a bottom cover 720 and a printed circuit board interposer 722. In certain embodiments, the bottom cover 720 and the printed circuit board interposer 722 are common to the storage cartridge module 700 regardless of whether the storage cartridge module is configured in a hot swap storage media access configuration or a locking configuration.

In certain embodiments, the bottom component 710 and the top cover 712 are configured to receive either a latch component 730 or a locking component 732. In certain embodiments, the bottom component 710 defines an attachment aperture 740, includes an attachment component 742, an attachment component 744, or a combination thereof. In certain embodiments, the attachment component 742 includes a nut. In certain embodiments, the attachment component 744 includes a nut. In certain embodiments, the attachment aperture 740, the attachment component 742, or a combination thereof, are used to attach a latch component 730 or a locking component 732 to the storage cartridge module 700. In certain embodiments, the attachment component 744 mates with a faster 750 to mount the top cover 712 to the bottom component 710.

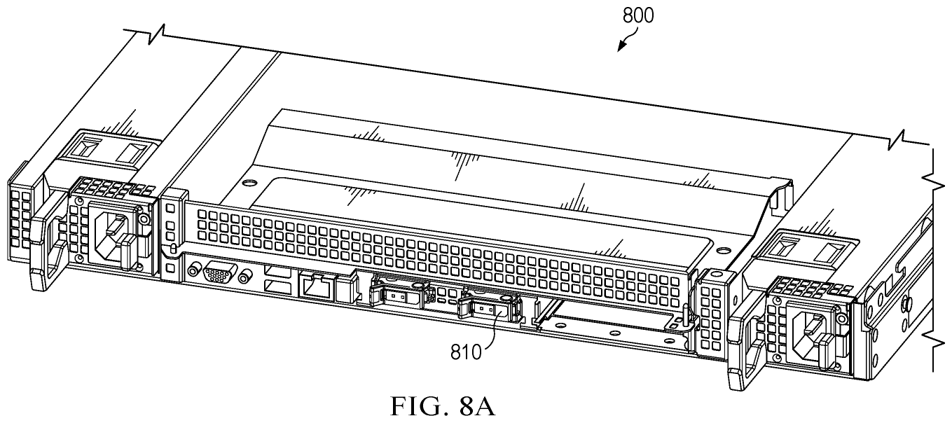

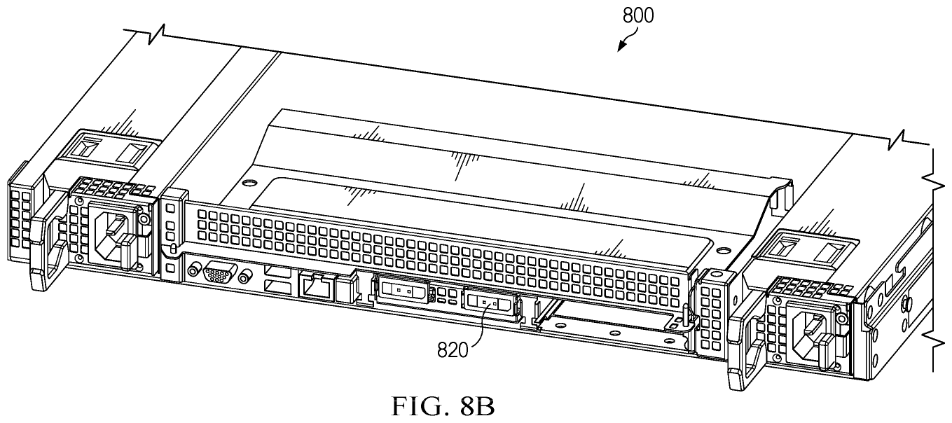

FIGS. 8A and 8B, generally referred to as FIG. 8, show examples of multi access option storage systems installed in an information handling system 800. More specifically, FIG. 8A shows multi access option storage systems installed in an information handling system 800 when the storage module system configured in a hot swap storage media access configuration 810. FIG. 8B shows multi access option storage systems installed in an information handling system 800 when the storage module system configured in a locking configuration 820. In certain embodiments, the storage module system 800 corresponds to storage module system 150.

In certain embodiments, when the storage module system is configured in a hot swap storage media access configuration, latch components of the storage module system allow a user to unlatch storage cartridge modules and remove the storage cartridge modules from the storage system.

When the storage module system is configured in a locking configuration, locking components prevent a user from easily removing storage cartridge modules from the storage module system. When the storage module system is configured in a locking configuration, users cannot access fastener of the storage module system when the storage module system is installed in the information handling system 800. In certain embodiments, when the storage module system is in a clocking configuration, storage cartridge modules of the storage module system can only be accessed by removing the information handling system from a rack in which the information handling system is installed.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A storage system housing for use with storage module system for an information handling system, comprising:
a bottom wall; and,
a front housing portion, the front housing portion extending substantially perpendicularly from the bottom wall, the front housing portion comprising a multi access option feature, the multi access option feature enabling a common storage system housing to be used with storage cartridge modules having a plurality of storage system access options.

2. The storage system housing of claim 1, wherein:
the plurality of storage system access options include a hot swap storage media access configuration and a locking storage media access configuration.

3. The storage system housing of claim 2, wherein:
the multi access option feature comprises a latching portion, the latching portion being configured to interact with a latch component of a storage cartridge module when the storage module system is in the swap storage media access configuration.

4. The storage system housing of claim 3, wherein:
the latching portion comprises a latch tab and latch aperture, the latch tab and latch aperture mating with a side latch portion of a latching component.

5. The storage system housing of claim 3, wherein:
the latching portion comprises a latch bump out, the latch bump out mating with a side latch portion of a latching component.

6. The storage system housing of claim 2, wherein:
the multi access option feature comprises a locking portion, the locking portion being configured to interact with a locking component of a storage cartridge module when the storage module system is in the locking storage media access configuration.

7. A storage system comprising:
a storage system cartridge module; and,
a storage system housing, the storage system housing comprising
a bottom wall; and,
a front housing portion, the front housing portion extending substantially perpendicularly from the bottom wall, the front housing portion comprising a multi access option feature, the multi access option feature enabling a common storage system housing to be used with storage cartridge modules having a plurality of storage system access options.

8. The storage system of claim 7, wherein:
the plurality of storage system access options include a hot swap storage media access configuration and a locking storage media access configuration.

9. The storage system of claim 2, wherein:
the multi access option feature comprises a latching portion, the latching portion being configured to interact with a latch component of the storage cartridge module when the storage module system is in the swap storage media access configuration.

10. The storage system of claim 3, wherein:
the latching portion comprises a latch tab and latch aperture, the latch tab and latch aperture mating with a side latch portion of a latching component.

11. The storage system of claim 3, wherein:
the latching portion comprises a latch bump out, the latch bump out mating with a side latch portion of a latching component.

12. The storage system of claim 8, wherein:
the multi access option feature comprises a locking portion, the locking portion being configured to interact with a locking component of the storage cartridge module when the storage module system is in the locking storage media access configuration.

13. A system comprising:
a chassis;
a processor contained within the chassis;
a data bus coupled to the processor; and,
a storage system comprising
a storage system cartridge module; and,
a storage system housing, the storage system housing comprising
a bottom wall; and,
a front housing portion, the front housing portion extending substantially perpendicularly from the bottom wall, the front housing portion comprising a multi access option feature, the multi access option feature enabling a common storage system housing to be used with storage cartridge modules having a plurality of storage system access options.

14. The system of claim 13, wherein:
the plurality of storage system access options include a hot swap storage media access configuration and a locking storage media access configuration.

15. The system of claim 14, wherein:
the multi access option feature comprises a latching portion, the latching portion being configured to interact with a latch component of the storage cartridge module when the storage module system is in the swap storage media access configuration.

16. The system of claim 15, wherein:
the latching portion comprises a latch tab and latch aperture, the latch tab and latch aperture mating with a side latch portion of a latching component.

17. The system of claim 15, wherein:
the latching portion comprises a latch bump out, the latch bump out mating with a side latch portion of a latching component.

18. The system of claim 14, wherein:
the multi access option feature comprises a locking portion, the locking portion being configured to interact with a locking component of the storage cartridge module when the storage module system is in the locking storage media access configuration.
